(19) United States
(12) Patent Application Publication
(10) Pub. No.: US 2026/0372121 A1
(43) Pub. Date: Nov. 19, 2026

(54) ELECTRONIC COMPONENT CARRIER WITH HEIGHT MISALIGNMENT BALANCING MECHANISM INTEGRATED IN THE CARRIER FOR FORMING LATERAL CONTACT

(71) Applicant: Infineon Technologies Austria AG, Villach (AT)

(72) Inventors: Ludwig Heitzer, Falkenfels (DE); Thorsten Meyer, Regensburg (DE); Christian Irrgang, Sinzing (DE); Frank Zudock, Sinzing (DE); Michael Bauer, Nittendorf (DE)

(21) Appl. No.: 19/680,289

(22) Filed: May 18, 2026

(30) Foreign Application Priority Data
May 19, 2025 (DE) 102025119325.8

(51) Int. Cl. H10W 70/40; H10W 70/04

(52) U.S. Cl. CPC H10W 70/411; H10W 70/04

(57) ABSTRACT

A carrier is provided for carrying and electrically connecting an electronic component having a plurality of downwardly protruding electrically conductive connection terminals for connection with the carrier. The carrier includes: a support structure configured to support the electronic component; a plurality of electrically conductive connection elements each configured to establish an electrically conductive connection with an assigned one of the electrically conductive connection terminals of the electronic component when the electronic component is supported by the support structure; and a height misalignment balancing mechanism integrated in the carrier. The height misalignment balancing mechanism is configured to balance a height misalignment between respective pairs of one of the electrically conductive connection elements and an assigned one of the electrically conductive connection terminals by electrically contacting the connection terminals laterally with the connection elements when the connection terminals are connected with the connection elements.

### TECHNICAL FIELD

The present disclosure relates to a carrier for carrying and electrically connecting an electronic component, a package, and a method of manufacturing a carrier for carrying and electrically connecting an electronic component.

### BACKGROUND

Packages may be denoted as encapsulated electronic components on a leadframe structure or another carrier with electrical connections extending out of the encapsulant and being mounted to an electronic periphery, for instance on a printed circuit board.

Packaging cost is an important driver for the industry. Related with this are performance, dimensions and reliability. The different packaging solutions are manifold and have to address the needs of the application.

### SUMMARY

There may be a need to provide a carrier for a package with high device reliability.

According to an exemplary embodiment, a carrier for carrying and electrically connecting an electronic component comprising a plurality of downwardly protruding electrically conductive connection terminals for connection with the carrier is provided, the carrier comprising a support structure for supporting a carried electronic component, a plurality of electrically conductive connection elements each for establishing an electrically conductive connection with an assigned one of said electrically conductive connection terminals of the electronic component when the electronic component is supported by the support structure, and a height misalignment balancing mechanism integrated in the carrier and configured for balancing a height misalignment between respective pairs of one of said electrically conductive connection elements and an assigned one of said electrically conductive connection terminals by electrically contacting the connection terminals laterally with the connection elements when the connection terminals are connected with the connection elements.

According to another exemplary embodiment, a package is provided which comprises a carrier having the above-mentioned features, and an electronic component comprising a plurality of downwardly protruding electrically conductive connection terminals and being connected with the carrier, wherein an electrically conductive connection is established between each respective pair of one of said electrically conductive connection elements and an assigned one of said electrically conductive connection terminals between which the height misalignment balancing mechanism balances a height misalignment by electrically contacting the connection terminals laterally with the connection elements.

According to still another exemplary embodiment, a method of manufacturing a carrier for carrying and electrically connecting an electronic component comprising a plurality of downwardly protruding electrically conductive connection terminals for connection with the carrier is provided, the method comprising providing a support structure for supporting an electronic component to be carried, forming a plurality of electrically conductive connection elements at the support structure and each for establishing an electrically conductive connection with an assigned one of said electrically conductive connection terminals of the electronic component when the electronic component is supported by the support structure, and integrating a height misalignment balancing mechanism in the support structure and configuring the height misalignment balancing mechanism for balancing a height misalignment between each respective pair of one of said electrically conductive connection elements and an assigned one of said electrically conductive connection terminals by electrically contacting the connection terminals laterally with the connection elements when the connection terminals are connected with the connection elements.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a cross-sectional view of a carrier and an electronic component to be connected for forming a package according to an exemplary embodiment prior to connection.

FIG. 2 illustrates a cross-sectional view of a package according to an exemplary embodiment obtained by connecting the carrier and the electronic component according to FIG. 1.

FIG. 3 illustrates a cross-sectional view of a carrier and an electronic component to be connected for forming a package according to an exemplary embodiment prior to connection.

FIG. 4 illustrates a cross-sectional view of a package according to an exemplary embodiment obtained by connecting the carrier and the electronic component according to FIG. 3.

FIG. 5 illustrates a cross-sectional view of a carrier and an electronic component to be connected for forming a package according to an exemplary embodiment prior to connection.

FIG. 6 illustrates a cross-sectional view of a package according to an exemplary embodiment obtained by connecting the carrier and the electronic component according to FIG. 5.

FIG. 7 illustrates a cross-sectional view of a carrier and an electronic component to be connected for forming a package according to an exemplary embodiment prior to connection.

FIG. 8 illustrates a cross-sectional view of a package according to an exemplary embodiment obtained by connecting the carrier and the electronic component according to FIG. 7.

FIG. 9 illustrates a plan view of a carrier for a package according to FIG. 7 and FIG. 8.

FIG. 10 illustrates a cross-sectional view of a preform of a carrier for a package according to an exemplary embodiment.

FIG. 11 illustrates a cross-sectional view of the carrier according to FIG. 10 in a completed state.

FIG. 12 illustrates a cross-sectional view of the carrier according to FIG. 11 and an electronic component to be connected for forming the package.

FIG. 13 illustrates a cross-sectional view of a package according to an exemplary embodiment obtained by connecting the carrier and the electronic component according to FIG. 12.

FIG. 14 illustrates a cross-sectional view of a carrier and an electronic component to be connected for forming a package according to an exemplary embodiment prior to connection.

FIG. 15 illustrates a cross-sectional view of a socket of the carrier according to FIG. 14.

FIG. 16 illustrates a cross-sectional view of a package according to an exemplary embodiment obtained by connecting the carrier and the electronic component according to FIG. 14.

FIG. 17 illustrates a cross-sectional view of a socket of a carrier of a package according to an exemplary embodiment.

FIG. 18 illustrates a cross-sectional view of a socket of a carrier of a package according to an exemplary embodiment.

FIG. 19 illustrates a cross-sectional view of a socket of a carrier of a package according to an exemplary embodiment.

FIG. 20 illustrates a cross-sectional view of a socket of a carrier of a package according to an exemplary embodiment.

### DETAILED DESCRIPTION

The examples described herein provide a carrier (such as a chip carrier substrate) to be connected electrically and mechanically with one or more electronic components (in particular a semiconductor die). Such an electronic component may have plural electrically conductive terminals (in particular metal pillars) which extend towards the carrier, for instance downwardly when the carrier is arranged beneath the electronic component ready for connection. The electrically conductive terminals of the electronic component are to be connected with corresponding electrically conductive connection elements of the carrier for establishing an electrically conductive connection between carrier and electronic component. For this purpose, the carrier comprises a support structure (for instance having interior electrically conductive structures for establishing an electrically conductive connection between the connection elements on top with pads on bottom). The support structure may, on the one hand, support an electronic component thereon. Simultaneously, the support structure with its electrically conductive connection elements may contribute to the formation of an electrically conductive connection between (for instance each) respective pairs of connection element and assigned terminal. Advantageously, a height misalignment balancing mechanism forming part of the carrier may be advantageously adapted to balance or compensate partially or entirely a potential height misalignment between carrier and electronic component due to different heights (for instance due to tolerances) of the terminals. This may be accomplished beneficially by electrically contacting the terminals (at least also) laterally with the connection elements (wherein an additional connection at a horizontal flange face of the terminals may be not excluded). When the height misalignment balancing mechanism forms part of the carrier only, not adaptation of the electronic component is necessary, which simplifies manufacture of the electronic component. To put it shortly, when an electric contact between connection elements and terminals is established sidewise rather than by a vertical abutment surface only, unintentionally long or short connection terminals (for instance metal pillars) will not cause contact problems, for instance in the event of tolerances. Thus, a carrier and a corresponding package with high device reliability may be obtained. Advantageously, an electric contact between a respective terminal and an assigned connection element may be established between a side wall of the terminal and/or a side wall of the connection element. To put it shortly, the metal pillars (or other kinds of terminals) can have heights which may differ from an equal or a target height, for example due to differences in an electroplating process for forming the terminals. This height difference may lead to some pillars (or other kinds of terminals) not connected, if only attached to a flat pad. According to embodiments, a height misalignment balancing mechanism may be designed for balancing or compensating the different heights of the plurality of metal pillars (or other kinds of terminals) of the component (such as a die).

In the following, further exemplary embodiments of the carrier, the package, and the method will be explained.

In the context of the present application, the term “carrier” may particularly denote a supporting structure (which may be at least partially electrically conductive) which serves as a mechanical support for the one or more electronic components to be mounted thereon, and which may also contribute to the electric interconnection of the electronic component(s), for instance between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad.

In the context of the present application, the term “electronic component” may in particular encompass a semiconductor chip (in particular a power semiconductor chip), an active electronic device (such as a transistor), etc. In particular, the electronic component may be a bare die or chip before encapsulated (for instance molded) with an encapsulant. In particular, the electronic component may be a semiconductor chip having at least one monolithically integrated circuit element (such as a diode or a transistor) in a surface portion thereof. The electronic component may be a naked die or may be already packaged or encapsulated. Semiconductor chips implemented according to exemplary embodiments may be formed for example in silicon technology, gallium nitride technology, silicon carbide technology, etc.

In the context of the present application, the term “terminal” may particularly denote an electrically conductive interface of the electronic component allowing access to an electronic main body (such as a semiconductor body) of the latter. For example, such a terminal may be a metal pillar or a metal pad. For instance, a metal pillar may have a vertical length or height in a range from 30µm to 500µm, in particular in a range from 50µm to 100µm. Typical tolerances of such pillar-type terminals may be in a range from 10% to 20%. For example, the terminal may comprise copper or aluminum. Different terminals of the electronic component may extend from the same main surface thereof. For instance, the terminals may extend downwardly when the electronic component is arranged above the carrier during a connection process, especially a die attachment process. It is also possible that one or more terminals are provided at each of the two opposing main surfaces of the electronic component. The terminals, e.g., metal pillars (for instance made of copper, aluminum, silver, etc.), pads, stud bumps, or any other vertical terminals extending from a bare die, can be attached or formed to the electronic component, e.g., a wafer or bare die cut from a wafer, in a FE (front end) process and/or in a BE (back end) process of a semiconductor device manufacturing process.

In the context of the present application, the term “connection element” may particularly denote an electrically conductive structure exposed at a connection surface of the carrier for connection with terminals of an electronic component to be connected with the carrier. A connection element may be configured to establish an electrically conductive connection with an assigned terminal of the electronic component sideways or laterally.

In the context of the present application, the term “height misalignment balancing mechanism” may particularly denote a configuration of the carrier which may allow to establish an electrically conductive connection between terminals of the electronic component and connection elements of the carrier regardless of a height misalignment of terminals and connection elements. Different heights may occur in the plurality of terminals and/or in the connection elements, since both may have height tolerances. In particular when different terminals protruding from the electronic component towards the carrier have different heights (for instance due to tolerances), so that a purely vertical abutment connection might fail for part of the terminals, the height misalignment balancing mechanism may nevertheless ensure reliable electric connection in between regardless of said height misalignment. For example, this may be achieved by forming connection recesses of the carrier deeper than the longest terminals for ensuring that all terminals (in particular even the longest one(s)) can be properly inserted into the recesses. When such sufficiently long recesses are combined with a lateral rather than vertical connection architecture between the connection elements and the terminals, height tolerance compensation may become possible.

In the context of the present application, the term “height misalignment balancing mechanism integrated in the carrier” may particularly denote that the height misalignment balancing mechanism may be completely due to a corresponding configuration of the carrier. Thus, no adaptation of the electronic component(s) may be necessary for height misalignment balancing. It may be sufficient to provide a carrier with a height misalignment balancing mechanism to reliably establish an electric connection between terminals of the electronic component and connection elements of the carrier. Thus, the height misalignment balancing mechanism may be an intrinsic property of the carrier.

In the context of the present application, the term “balancing height misalignment between a connection element and an assigned connection terminal” may particularly denote ensuring a reliable electric connection between connection elements and terminals regardless of height variations between different terminals and/or variations of height values of the terminals from a respective target value.

In the context of the present application, the term “electrically contacting connection terminals laterally with the connection elements” may particularly denote that the electric connection between terminals and connection elements may be arranged at least partially at a side surface of the terminals. For example when the terminals are metal pillars and extend downwardly from a main body of a respective electronic component towards the carrier, realizing the electric connection with connection elements of the carrier at a lateral surface or side wall of connection elements and/or terminals may ensure proper electric connection even when a vertical misalignment of the terminals with respect to the connection element occurs.

In the context of the present application, the term “package” may particularly denote an electronic device which may comprise one or more electronic components mounted on a carrier, said carrier to comprise or consist out of a single part, multiple parts joined via encapsulation or other package components, or a subassembly of carriers. In preferred embodiments, said constituents of the package are encapsulated at least partially by an encapsulant. Optionally, one or more electrically conductive interconnect bodies (such as bond wires and/or clips) may be implemented in a package, for instance for electrically coupling the electronic component with the carrier.

In an embodiment, the support structure comprises a plurality of sockets in which the height misalignment balancing mechanism is integrated, wherein each socket comprises a respective one of the electrically conductive connection elements (in particular at a sidewall of the socket) and is configured for receiving a plugged-in respective electrically conductive connection terminal of the electronic component. The depth of an insertion recess of the sockets may be at least as large as the height of the terminal with the longest height. By a plug and socket configuration of an electronic component and a carrier, an intuitive and reliable connection may be established by merely plugging in the downwardly protruding terminals of the electronic component into the assigned sockets of the carrier. During this plug in procedure, lateral electrically conductive contact of the socket will be established with lateral contacts of the terminals. Optionally, there may also be in addition a vertical abutment of the downwardly protruding terminals against connection elements in the socket.

In an embodiment, the sockets are formed in recesses in the support structure and/or protrude vertically beyond the support structure. When the sockets are formed as indentations in the support structure, a highly compact package may be formed by plugging together sockets and protruding terminals. When the sockets are formed as protrusions beyond a main surface of the support structure (for instance as surface-mounted devices), a highly intuitive connection may become possible and the sockets may function already at an early stage of the plug in procedure as a guide for properly ensuring alignment between terminals and connection elements.

In an embodiment, the height misalignment balancing mechanism is formed by at least partially deformable connection elements. The deformable connection elements may be elastically deformed or plastically deformed upon establishing a contact force between terminals and connection elements. Elastically or plastically deformable connection elements may be deformed by the insertion force of the protruding terminals when getting into contact with the deformable connection elements. This may ensure a highly reliable and failure robust connection mechanism.

In an embodiment, the at least partially deformable connection elements comprise deformable electrically conductive medium, in particular electrically conductive glue, electrically conductive paste and/or sinter paste. Such embodiments are shown, for example, in FIGS. 3 OR 4. A preferred option for an at least partially deformable connection element is copper paste which may be inserted into a socket for establishing an electrically conductive contact between terminals and connection elements at a lateral surface area and optionally in addition at a for instance horizontal flange face of the terminals. Further options for the at least partially deformable connection elements are deformable solder (for instance solder paste) and/or glue (in particular electrically conductive glue).

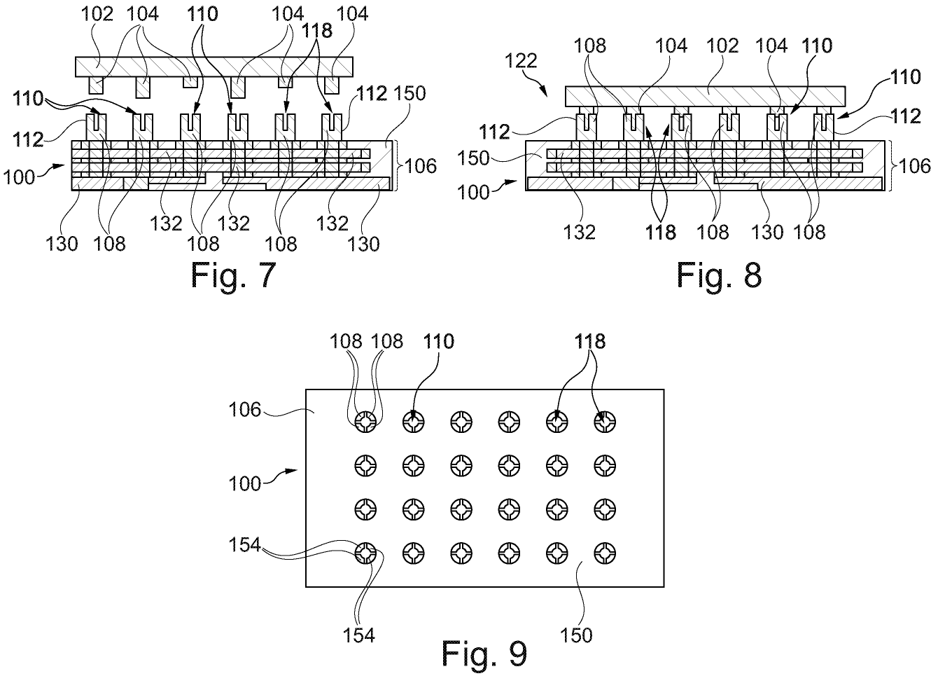

In an embodiment, the at least partially deformable connection elements form part of deformable sockets, in particular springy sockets. Such embodiments are illustrated in FIGS. 7-9. When the protruding terminals are inserted into the sockets having deformable electrically conductive connection elements, the plug in force of the terminals may displace the springy connection elements outwardly, wherein a restoring spring force may press the connection elements against a lateral surface of the terminals to thereby establish a reliable electric contact in between. For instance, the springy sockets may be configured as flat springs with tongues of electrically conductive material, etc. For example, sockets made of copper and having elastic properties may be used.

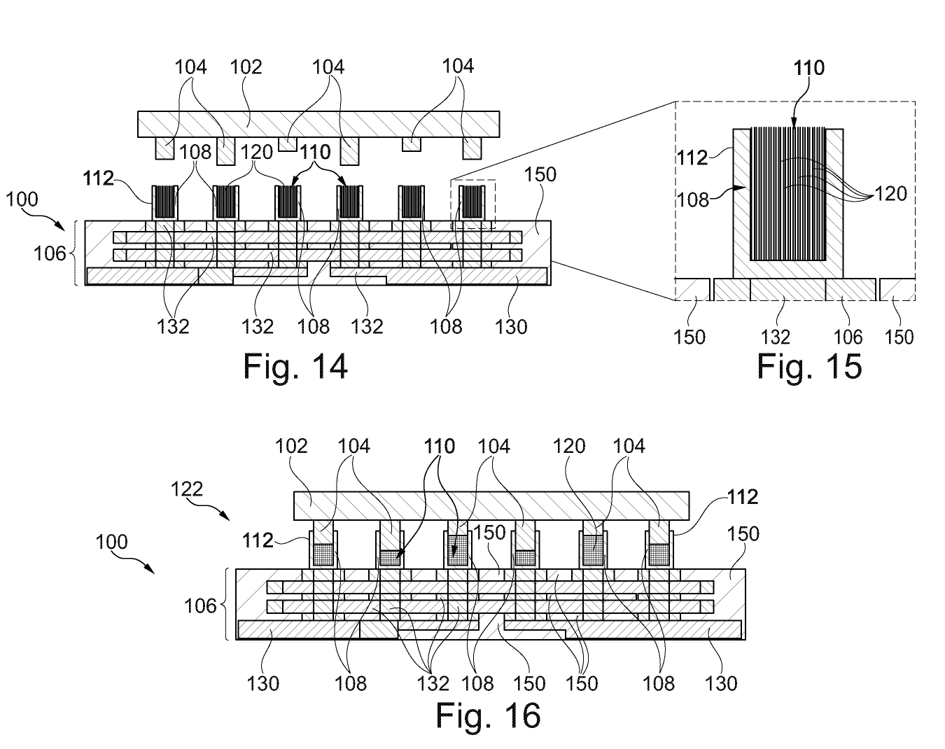

In an embodiment, the at least partially deformable connection elements comprise deformable fine structures. Corresponding embodiments are shown in FIGS. 14-20. The fine structures may be made of deformable electrically conductive material. For instance, the fine structures may comprise metallic hair structures extending from a socket base and being displaced laterally and/or vertically upon inserting the protruding terminals into the sockets filled partially or entirely with the fine structures. In particular, the fine structures may be plastically deformable when inserting the terminals in the sockets. Other examples of the fine structures are porous metal structures, metallic wave structures, metallic side wall structures extending from socket sidewalls and filling only part of the socket recess, metallic ribs, etc.

In an embodiment, the height misalignment balancing mechanism is formed by flexible electrically conductive connection elements. In one embodiment, said flexible electrically conductive connection elements are elastic, i.e. return in their initial configuration when unplugging the terminals. In another embodiment, the flexible electrically conductive connection elements are permanently deformed upon inserting the terminals, i.e. to not return into their initial configuration when removing the terminals out of the sockets.

In an embodiment, the flexible electrically conductive connection elements are arranged or anchored at a lateral wall of the sockets. This may ensure that a lateral electrically conductive connection between terminals and connection elements is created by the connection procedure, thereby reliably compensating potential height misalignment between different terminals and/or between a respective terminal and a respective connection element or socket.

In an embodiment, the flexible electrically conductive connection elements are helical structures or leaf springs. Such a helical structure or such a leaf (or flat) spring may be compressed during an insertion process, so that a back driving force exerted by the helical structure or leaf spring creates a highly reliable connection force or pressure forcing the connection elements against the terminals.

In an embodiment, the flexible electrically conductive connection elements are slotted sleeves, in particular longitudinally slotted sleeves. Metallic sleeves can be manufactured very easily. By slotting such metallic sleeves, springy structures or tongues are created which can be displaced laterally upon inserting terminals. A Hooke force of displaced metallic sleeves may bias them against the terminals, thereby improving the reliability of the electric connection even in the presence of a height misalignment.

In an embodiment, the electrically conductive connection elements comprise fine structures (which may be, for example, clamping structures), in particular nano-structures, metallic hair structures and/or metallic ribs. Such embodiments are shown in FIGS. 14-20. For example, nano-structures may be filament structures that have a diameter in a range from 1nm to 800nm, for example in a range from 100nm to 200nm. The length of such nano-structures may be larger than their diameter, for instance may be at least ten times of their diameter. The fine structures may, however, also be micro-structures. For instance, micro-structures may be filament structures having a diameter in a range from 1µm to 10µm. Such structures are sufficiently rigid for ensuring a proper electric contact with the terminals and may also carry, when taken together, sufficient electric current. At the same time, such structures may be capable of being displaced with moderate connection forces, thereby ensuring a reliable electric connection at least partially sidewise.

In an embodiment, the height misalignment balancing mechanism is configured for connecting the electrically conductive connection elements with the electrically conductive connection terminals by mechanically clamping only. Hence, the connection may be established without any chemical processes and thus without heating, curing, chemical reactions, etc. It may be very simple to establish a connection between carrier and electronic component by applying exclusively a mechanical clamping force.

In an embodiment, the support structure is configured as one of a Molded Interconnect Substrate (MIS), a laminate substrate, a ceramic substrate and a leadframe structure.

An MIS substrate may be a preferred option. In the context of the present application, the term “Molded Interconnect Substrate” (MIS) may particularly denote a substrate comprising a mold compound as matrix on and/or in which electrically conductive traces (in particular made of copper) are formed. With embedded copper traces, an MIS may enable a fine line and space that is needed for high input/output count with small form factor. An MIS substrate also supports chip mounting in flip chip configuration. An MIS substrate may comprise copper filled vias and/or filled pads. An MIS substrate may be a preferred embodiment of the support structure, since the corresponding production flow may allow to realize the formation of lateral clamping structures or other connection elements capable of establishing a lateral electrically conductive connection with vertically protruding terminals of an electronic component upon assembling carrier and electronic component. A reason for this is that an MIS substrate may be manufactured by additive manufacturing. After having formed such connection structures, and optionally further electrically conductive structures connected with the connection elements, a mold compound may be provided.

In the context of the present application, the term “laminate” may particularly denote a flat body (such as a sheet or plate) formed by multiple interconnected laminate layers, i.e. layers which can be or which are interconnected by lamination. In particular, a laminate may comprise a material that is suitable for sticking several laminate layers, for instance made of the same material, together. Hence, a laminate may be a plate-shaped or sheet-shaped body made of one or multiple laminable or laminated layers. Said laminate layers may be connected or configured to be connectable with other layers by lamination. Lamination may denote a connection of laminable layers using elevated temperature, optionally accompanied by an additional mechanical pressure applied to stacked laminate layers. In particular, such a laminate may be a pressed multilayer stack of one or more dielectric organic layers and/or one or more metallic foils. One or more dielectric laminate layers may be for example prepreg layers. Prepreg is a material which comprises a resin, optionally with glass particles therein. The laminate may also comprise one or more metal layers, which may be copper foils. More generally, the laminate may comprise at least one dielectric layer which is capable of curing, polymerizing and/or cross-linking during a lamination process, thereby contributing to an adhesion force between multiple layers of a multilayer laminate. For instance, a laminate may be a chip substrate or a printed circuit board (PCB). By using a laminate substrate or carrier, the electric interconnection of the at least one electronic component may be further refined.

In the context of the present application, the term “ceramic carrier” may particularly denote a carrier comprising a ceramic substance or material, in particular as main constituent. Examples are carriers comprising a base body comprising a ceramic (for instance aluminum nitride, silicon nitride, aluminum oxide). An example for a ceramic carrier is a carrier comprising a sheet or plate made of a ceramic material and being covered on one or both opposing main surfaces thereof with a metal layer, wherein such a metal layer may be patterned or continuous. It is for example possible that the mentioned carrier is a DAB (Direct Aluminum Bonding) substrate, a DCB (Direct Copper Bonding) substrate, etc. Moreover, the carrier may also be configured as Active Metal Brazing (AMB) substrate.

In the context of the present application, the term “leadframe” may particularly denote a sheet-like metallic structure which can be bent, punched and/or patterned so as to form leadframe bodies as die pad, and optionally connection leads for electric connection of the package to an electronic environment. In an embodiment, the leadframe may be a metal plate (in particular made of copper) which may be patterned, for instance by stamping or etching. Such a leadframe structure may simply be placed below the flip-chip mounted electronic component and connected with it. For instance, such a leadframe may be a patterned metal sheet made of copper and/or aluminum. A leadframe may be a full metal leadframe or a pre-molded leadframe which may have several piece of metal held and kept separated by a mold compound. Any of these two types of carriers are possible. A purely metallic leadframe may be a carrier of an exemplary embodiment. A pre-molded leadframe (or also called “Routable Substrate”) may be considered as an intermediate between a purely metallic leadframe and an MIS, and can also be used in exemplary embodiments. A difference to purely metallic leadframe is, that the metal is held together by the mold compound prior to die attach. A difference to an MIS is that the MIS may be typically provided in an additive process, while at least the first layer of a routable substrate is generated by subtractive processing (for example by etching).

In an embodiment, the height misalignment balancing mechanism is configured for balancing misalignment by arranging the connection elements at sockets for connection to a sidewall of the connection terminals when plugged in the sockets. Advantageously, the height difference among the connection terminals does not matter with such a design.

In an embodiment, the support structure comprises a plurality of exposed electrically conductive pads at a bottom of the support structure and comprises a plurality of internal electrically conductive traces, said traces electrically connecting the connection elements to the pads. This may provide routability of the support structure. This may be advantageous, especially for the final semiconductor package. To put it shortly, one or more electronic components, such as semiconductor dies, may be mounted (preferably in flip chip configuration) on a top main surface of the support structure so that the terminals are electrically coupled laterally with the connection elements. Electric signals may be conducted from or to the electronic component via the terminals, the connection elements and the traces in an interior of the support structure, which may be preferably a Metal Interconnect Substrate. From the traces, an electric coupling with the pads on the bottom main surface of the support structure may be established. By taking this measure, short electric paths can be established between the electronic component and the bottom side of the support structure or the carrier. This may lead to low losses and low heat dissipation.

In an embodiment, the electronic component is connected with the carrier in a flip-chip configuration. In the context of the present application, the term “flip-chip configuration” may particularly denote a configuration of a chip in which the chip is mounted on a carrier with its active region and/or terminals facing the carrier. The active region of the chip may be a surface region in which at least one integrated circuit element is integrated, in particular monolithically integrated. In a flip-chip attachment or arrangement, the chip or die may be attached to the carrier using a flip-chip method. The front side of the chip may face the carrier in a flip-chip configuration, whereas the back side of the chip may oppose the carrier. Advantageously, metal pillars may be used as terminals arranged on the bottom side of the flip chip electronic component so as to directly face the upper main surface of the carrier with the connection elements.

In an embodiment, the electrically conductive connection terminals and the electrically conductive connection elements are configured for establishing a high-current capable electrically conductive connection. For instance, the reliability of the electric connection between terminals and connection elements may be so that a current of at least 1 Ampere, preferably at least 10 Ampere, may be conducted between the electronic component and the carrier.

In an embodiment, the electrically conductive connection terminals and the electrically conductive connection elements comprise or consist of the same material, for example copper. Advantageously, a one-metal approach (for instance a copper-copper connection) may avoid material bridges at an electric interface between electronic component and carrier and may suppress undesired migration effects.

In an embodiment, the electronic component is a semiconductor chip, in particular a bare die, a vertical power chip and/or a lateral power chip. “Vertical” and “lateral” refers to the current flow in the die. Embodiments may use components with lateral current flow (which may be logic components). Other embodiments may use components with vertical current flow (which may be power dies, like MOSFETs). For instance, it may be a lateral die. In particular, it may be a gallium nitride die. In the context of the present application, the term “lateral chip” may particularly denote a chip being configured as a lateral device. This may be in contrast to a vertical device experiencing a vertical current flow during operation. Such a lateral chip may be configured so that, during operation, charge carriers flow along (or flow predominantly along) a lateral or horizontal direction (in particular rather than along a vertical direction). In contrast to vertical chips, the dominant current flow of lateral chips may be in a direction within a horizontal plane, in particular in parallel to a semiconductor substrate surface. For instance, all chip pads or terminals of a lateral chip may be on the same main surface of the chip. Due to the flip-chip configuration of an electronic component of a package according to an exemplary embodiment, all chip terminals may be on the front side of the chip facing the carrier. Advantageously, a gallium nitride (GaN) chip may be realized in lateral device technology. Such a lateral device may generate heat during operation only on one main surface thereof, which may simplify heat removal by focusing on said region. Other embodiments may use components with vertical current flow which may have terminals on both opposing main surfaces of the component (for instance drain on one side, and source and gate on the other side). The connection architecture according to exemplary embodiments may be applied to one or more terminals on one or on both opposing main surfaces.

In an embodiment, at least two different terminals have different heights. In particular, different ones of the downwardly protruding electrically conductive connection terminals may have different heights. For instance, copper pillars on chip may be formed at a front-end process or a back-end process. The “different heights” may be calculated from a non-conductive bottom surface of the electronic component (such as a die) to the tip or free end of the terminal (for instance a copper pillar). The electrically protruding connection terminals may be generated by electroplating into resist openings. Due to this process, height tolerances between the different pillars may appear. Density variations of the vias, opening diameter variations and some other facts may influence the height differences. The values of those tolerances may depend on the height of the pillar. For a 60µm high pillar for example, the tolerance may be below ±10µm, in particular in one slot below ±5µm. Less height means less tolerances. The slower the process is run, the smaller are the height differences.

In an embodiment, the downwardly protruding electrically conductive connection terminals comprise metal pillars and/or metal pads. For example, a metal pillar may have an aspect ratio (i.e. a ratio between height and diameter) of at least 0.5, preferably of at least 1, in particular of the at least 2. A pad may be flat but may have, nevertheless, a certain vertical extension or height.

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in gallium nitride or silicon carbide technology.

For optionally encapsulating the package, a plastic-like material or a ceramic material which may be subsidized by encapsulant additives such as filler particles, additional resins or others may be used. Preferably, a mold compound may be used.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

Before exemplary embodiments will be described in more detail referring to the figures, some general considerations will be summarized based on which exemplary embodiments have been developed.

Copper to copper bonding may be an upcoming interconnect technology, especially for high power applications like gallium nitride (GaN) packages. The interconnection between die and substrate needs to provide a strong mechanical stability to ensure reliability, and as well provide an excellent electric and thermal conductivity in order to handle high current and power densities. Therefore, such packages are typically realized in flip-chip (FC) configuration with copper pillars on die pads. Conventionally, these copper pillars are attached to the substrate by common bonding procedures like soldering. One approach is the FC-assembly of GaN dies on a so-called MIS (Molded Interconnect Substrate) for mid-voltage applications. This kind of substrate provides high metal-densities and very good routing possibilities. Nevertheless, additional materials like solder, especially copper paste, are needed to form the interconnect between die and substrate. With increasing demand for higher current densities in this kind of applications, the risk for electromigration is also increasing. Electromigration itself can lead to Kirkendall voids and with this severe reliability concerns during usage of the power devices.

In order to overcome this issue for electromigration due to additional materials, mono-material-interconnects like copper-copper may be a possible solution with several advantages. Beside avoiding Kirkendall voids, this kind of connection is providing a lower thermal and electrical resistivity caused by the use of different materials and their interfaces to each other. Furthermore, the coefficient of thermal expansion (CTE) mismatch can be reduced significantly, and the package may be free of lead (Pb), according to environmental regularities and for decarbonization.

According to an exemplary embodiment, a carrier, for example a Molded Interconnect Substrate (MIS), may be connected in a highly reliable way for establishing an electric and mechanical connection with at least one electronic component (such as a semiconductor power die). Multiple electrically conductive terminals (such as copper pillars extending from a chip) of the electronic component may face a connection surface of the carrier. The terminals of the electronic component can be connected with assigned connection elements of the carrier for ensuring a reliable electrically conductive connection between the terminals and the connection elements. A support structure of the carrier may mechanically support a carried electronic component. At the same time, the support structure can establish an electrically conductive connection between the connection elements and the terminals. Beneficially, a height misalignment balancing mechanism of the carrier, i.e. being provided regardless of the design of the electronic component, may be configured to at least partially balance a possible height misalignment between each pair composed of a connection element and an assigned connection terminal. This can be achieved advantageously by electrically contacting the terminals laterally rather than (only) vertically with the connection elements. When an electric contact between connection element and terminal is established via sidewalls instead of vertically only (in particular when the terminals are plugged in socket-type connection elements), even excessively long or short connection terminals (for instance metal pillars) do not lead to contact issues. Hence, a carrier and a corresponding package with high device reliability may be obtained.

In particular, a connection between terminals and connection elements of the same material, in particular a copper-copper interconnection, may be advantageous to prevent electromigration phenomena. When combining this with a plug interconnection between terminals of the electronic component and connection elements of the carrier, it may be possible to compensate tolerances by establishing a lateral substrate-to-component connection, preferably with a one-material interconnect. To put it shortly, height tolerances may be compensated by establishing a clamping connection involving a lateral side of terminals and/or connection elements in the electric contact formation. It may be advantageous to avoid the use of multiple materials in the interconnect, especially the use of solder involving a further material. Solder might bridge the different heights of the interconnects, but it has a poor electrical/thermal resistance and it changes over time (building of intermetallic structures). Also, void formation may occur at high currents. Advantageously, this is not the case for a mono-material interconnect, especially copper, but copper is very hard and brittle, and it may be made feasible to connect it by bridging tolerances by height misalignment compensation according to exemplary embodiments.

When being connected with the carrier, the electronic component may be in a flip chip configuration. In such a flip chip configuration, some or all terminals of the electronic component may be arranged face-down, i.e. facing the connection surface of the carrier. Between the electronic component and carrier, a plug contact may be established. Preferably, metallic terminals and metallic connection elements may be made of the same material, most preferably copper. This avoids material bridges and suppresses artefacts or defects caused by electromigration (such as Kirkendall voids). A single material terminal-to-connection element coupling may be advantageous. In particular, exemplary embodiments may be advantageous for flip chip configurations in combination with metal pillars (preferably copper pillars) as terminals.

The terminals and/or the connection elements may be arranged in an array or in a matrix configuration on substrate and/or chip side, in particular one- or two-dimensionally.

Preferably, a socket on the carrier or substrate side may provide a flexible part of the connection and may thereby contribute to the height misalignment balancing mechanism.

An embodiment may provide a high-current-capable mono-material-interconnect (for example copper-copper) between a flip-chip-assembled die (for example a GaN die) and a carrier or substrate by an integrated plug interconnect mechanism which may be realized by the carrier or substrate configuration or manufacturing process. With such an embodiment, pillar height tolerances as well as the risk for cracking and/or delamination can be reduced or even overcome. This may enable to provide a highly reliable, low-ohmic connection within power packages.

In an embodiment, a specifically configured carrier or substrate may be provided with sockets for plug-in contact between terminals and connection elements. These contacts may be preferably designed in such a way that they are generated by the carrier itself, in particular via the carrier or substrate manufacturing process. The corresponding height misalignment balancing mechanism may thus be integrated directly into the carrier or substrate, and does not have to be assembled separately in this embodiment. Especially carrier or substrate technologies with a high flexibility in view of design rules like MIS (Molded Interconnect Substrate) may be particularly appropriate to form the basis of a carrier according to an exemplary embodiment.

Depending on the embodiment of the contact, the copper pillar or other protruding terminal may generate a direct mechanical contact with the carrier or substrate and may compensate all tolerances of the metal pillar. In an embodiment, a special plug-in design may enable a direct metal-metal (for example copper-copper) interconnect. In such an embodiment, a high temperature- and pressure-robust assembly may be used to generate this. In yet another embodiment, it may be possible to combine this design with glue or solder material, which gives even more margin for assembly and manufacturing tolerances.

Further details of the aforementioned embodiments will be mentioned in the following:

In one embodiment, the carrier may be provided with a socket with flexible sides or a helical structure. Sockets may be provided on the substrate side, and (for example copper) pillars may be plugged in the socket regardless of the height of the pillars by a clamping connection only.

In another embodiment, the carrier may be provided with a socket in combination with additional interconnect material, for example electrically conductive glue. Advantageously, the interconnect material may comprise the same metal as the pillars so that the pillars may be interconnected with recesses of the substrate by a plug-in connection. For instance, copper paste or sinter paste (for instance comprising copper) may be used as interconnect material.

In yet another embodiment, the carrier may be equipped with a socket being filled only partially or entirely with compensation structures, such as fine structures made of a metallic material (in particular copper). Preferably, copper compensation structures or fine structures may be used, for example copper hairs or fins or rips. When plugging in terminals (for instance pillars) into the socket filled with the fine structures, the fine structures may be pushed away and/or may be deformed so that they will sidestep laterally, thereby establishing an electrically conductive connection between the fine structure-type connection elements and the pillar-type or pad-type terminals. For example, the fine structures may comprise an array of metallic hair such as an electroplated grass of copper. In another example, the fine structures may comprise porous metal structures, such as a foam of copper which can be deformed.

After having connected the carrier with the at least one electronic component, for instance, in a flip chip configuration, the obtained structure or package can be further processed. Said further processing may comprise forming an underfill, encapsulating (for instance molding), etc.

Exemplary applications of exemplary embodiments are carriers and packages for providing a high-current capable interconnect between electronic component (for instance a GaN die) and carrier (for instance an MIS substrate). This may allow to support high performance applications, such as the handling of high power densities. In particular, packages according to exemplary embodiments may be packages comprising at least one power semiconductor chip, for instance manufactured in gallium nitride technology.

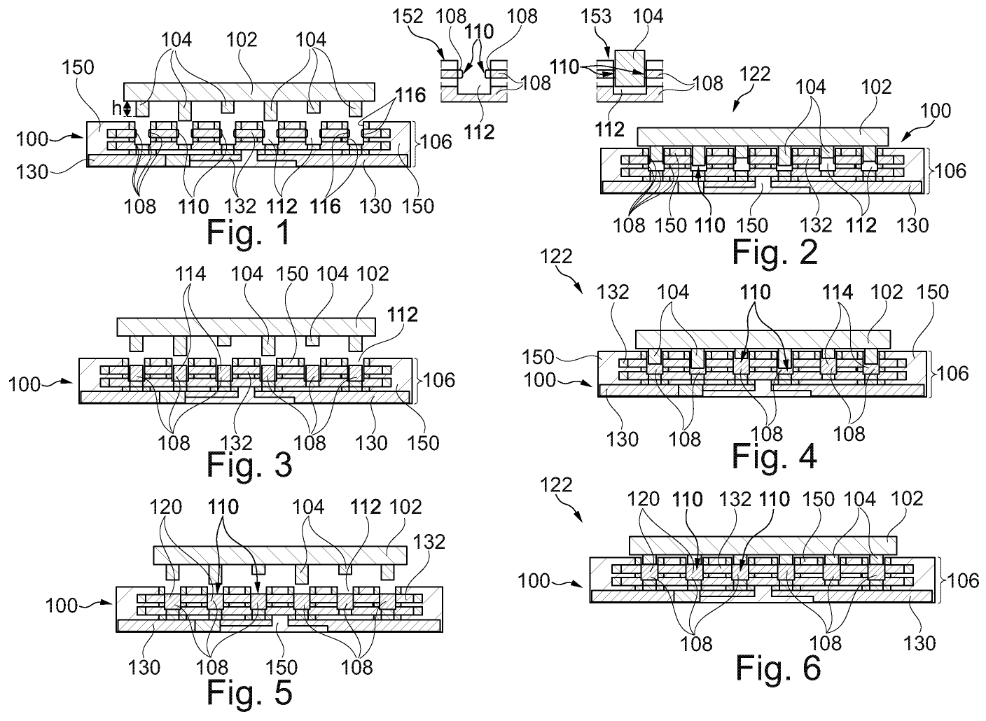

FIG. 1 illustrates a cross-sectional view of a carrier 100 and an electronic component 102 to be connected for forming a package 122 according to an exemplary embodiment prior to connection.

The bottom side of FIG. 1 illustrates the carrier 100 for carrying and electrically connecting the electronic component 102 which is shown on the top side of FIG. 1.

The electronic component 102 can be a semiconductor die, for instance a bare die. Said semiconductor die may be a semiconductor power die, for instance a transistor chip for high power applications. At least one monolithically integrated circuit (for instance an integrated transistor such as a field effect transistor, a diode, etc.) may be formed in an active region of the semiconductor die, for instance in a bottom-sided surface portion according to FIG. 1. As shown, the electronic component 102 comprises a plurality of downwardly protruding electrically conductive connection terminals 104 for electric connection with the carrier 100. In the illustrated embodiment, the electronic component 102 has all electrically conductive connection terminals 104 at one main surface thereof, which is the bottom main surface according to FIG. 1. The electronic component 102 may be a lateral die experiencing a horizontal current flow during operation. For example, the electronic component 102 embodied as a semiconductor die may be configured as gallium nitride (GaN) die. As shown in FIG. 1 as well, the electronic component 102 is arranged in a flip chip configuration with all terminals 104 face down, i.e. facing towards a connection surface of the carrier 100. In the shown embodiment, the terminals 104 are metal pillars.

Said carrier 100 may be equipped with a for instance plate-shaped or cuboid-shaped support structure 106 for supporting the electronic component 102 when carried by the carrier 100 in the assembled state according to FIG. 2. Said support structure 106 may be embodied preferably as Molded Interconnect Substrate (MIS). More specifically, the support structure 106 may comprise a plurality of exposed electrically conductive pads 130 at a bottom of the support structure 106. Moreover, the support structure 106 may comprise a plurality of internal electrically conductive traces 132 which may be in contact with mold compound. Said traces 132 may electrically connect connection elements 108 arranged and exposed in a socket 112 of the support structure 106 to the pads 130. Preferably, pads 130, traces 132 and connection elements 108 may be coupled with each other electrically. They may all be made of the same electrically conductive material, such as copper. This may suppress undesired migration phenomenon which may improve reliability. Moreover, pads 130, traces 132 and connection elements 108 may all be embedded in an electrically insulating matrix 150, which may be a mold compound. The described configuration may equip the carrier 100 with a routing capability.

The plurality of electrically conductive connection elements 108 of the carrier 100 exposed in the carrier-internal sockets 112 are each configured for establishing an electrically conductive connection with an assigned one of said electrically conductive connection terminals 104 of the electronic component 102, when the electronic component 102 is supported by the support structure 106 (i.e. after the transition of FIG. 1 to FIG. 2).

Advantageously, a height misalignment balancing mechanism 110 is integrated in the carrier 100. Said height misalignment balancing mechanism 110 is configured for balancing a potential height misalignment between respective pairs of one of said electrically conductive connection elements 108 and an assigned one of said electrically conductive connection terminals 104. As can be taken from FIG. 1, the different terminals 104 protruding downwardly from the electronic component 102 may have different vertical heights “h”, for instance due to manufacturing tolerances. Beneficially, by electrically contacting the connection terminals 104 laterally with the connection elements 108 when the connection terminals 104 are connected with the connection elements 108 may allow to achieve a reliable electric connection between connection elements 108 and terminals 104 even in the event of height tolerances. While conventionally a purely vertical connection between a bottom-sided horizontal flange face of the terminals 104 and horizontal connection elements 108 is established which may fail in the event of height misalignment, realizing an electric connection between connection elements 108 and terminals 104 at a side wall of the connection elements 108 in the socket 112 and at a side wall of the metal pillar-type terminals 104 may reliably ensure electric contact between terminals 108 and connection elements 108 even in the event of a significant height misalignment of terminals 104 and/or sockets 112 with connection elements 108. Hence, a horizontal or lateral rather than purely vertical connection between terminals 104 and connection elements 108 may provide a height tolerance-robust interconnection system. Advantageously, a depth of an insertion recess of each of the sockets 112 may be as large as or larger than the height of the terminal 104 with the longest height among all terminals 104. It is also possible that a depth of an insertion recess of each of the sockets 112 may be as large as or larger than the largest height of a terminal with a maximum tolerance of an allowed specification.

Now referring in further detail to the connection architecture of the carrier 100 of FIG. 1, its support structure 106 may comprises a plurality of sockets 112 in which the height misalignment balancing mechanism 110 is integrated. For example, the sockets 112 may be arranged along a one-dimensional array (for instance along a straight line) or a two-dimensional array (for example in a matrix like pattern, i.e. along rows and columns). For the purpose of height misalignment balancing, each socket 112 comprises a respective one of the electrically conductive connection elements 108 and is configured for receiving a plugged-in respective electrically conductive connection terminal 104 of the electronic component 102. Such a plug in procedure corresponds to the transition of FIGS. 1-2. In the illustrated embodiment, the sockets 112 are formed in recesses in the support structure 106.

In the embodiment of FIGS. 1 and 2, the height misalignment balancing mechanism 110 is formed by deformable connection elements 108 at sidewalls of the sockets 112. So in this embodiment, the height misalignment balancing mechanism 110 can be part of the socket 112 to solve the problem of different heights. Hence, the height misalignment balancing mechanism 110 of FIGS. 1 and 2 is formed by flexible electrically conductive connection elements 108. More specifically, the flexible electrically conductive connection elements 108 are arranged at a lateral wall 116 of the sockets 112. As illustrated schematically in FIGS. 1 and 2, springy electrically conductive structures extend from sidewalls of the carrier 100 exposed in the sockets 112 into the recesses (see detail 152 in FIG. 1). For instance, said springy structures may be flat springs or leaf springs. Alternatively, they may also be helical springs (not shown). When the terminals 104 protruding downwardly from the electronic component 102 are inserted into the sockets 112 as shown in FIG. 2 (see detail 153 in FIG. 2), the downwardly protruding pillar-type terminals 104 push the springy structures laterally out of the recess towards the sidewalls of the sockets 112. In this compressed configuration, the springy structures apply a biasing force to the terminals 104 inhibiting unplugging of the electronic component 102 and ensuring a reliable electric contact between terminals 104 and contact elements 108 exclusively by clamping. Thus, the height misalignment balancing mechanism 110 is configured for connecting the electrically conductive connection elements 108 with the electrically conductive connection terminals 104 by mechanically clamping only. This may lead to a reliable electric contact and a simple assembly process while ensuring a failure robust connection. Advantageously, the height misalignment balancing mechanism 110 is configured for balancing misalignment by arranging the connection elements 108 at sockets 112 for connection to a sidewall of the connection terminals 104 when plugged in the sockets 112.

Thus, the embodiment of FIG. 1 provides sockets 112 with flexible sides (or alternatively helical structures, not shown) for promoting a plug-in assembly. FIG. 1 shows the substrate or carrier 100 together with an electronic component 102 in flip chip configuration with copper pillar (without solder plating) before assembly.

FIG. 2 illustrates a cross-sectional view of a package 122 according to an exemplary embodiment obtained by connecting the carrier 100 and the electronic component 102 according to FIG. 1. The package 122 shown in FIG. 2 is obtained when interconnecting the electronic component 102 oriented in flip chip configuration according to FIG. 1 with downwardly protruding terminals 104 aligned with respect to the sockets 112 with connection elements 108 of the carrier 100. A plug-in connection of electronic component 102 and carrier 100 is sufficient for obtaining package 122.

The mentioned package 122 comprises the carrier 100 described according to FIG. 1 and the electronic component 102 illustrated according to FIG. 1. The downwardly protruding electrically conductive connection terminals 104 of the electronic component 102 are connected sideways with the conductive elements 108 in the sockets 112 of the carrier 100 by a mere plug-in connection. Thus, an electrically conductive connection is established between respective pairs of one of said electrically conductive connection elements 108 and an assigned one of said electrically conductive connection terminals 104 between which the height misalignment balancing mechanism 110 balances a height misalignment by electrically contacting the connection terminals 104 laterally with the connection elements 108.

The electrically conductive connection terminals 104, the electrically conductive connection elements 108 and the interconnection between the terminals 104 and the connection elements 108 in the way as shown in FIGS. 1 and 2 involving the height misalignment balancing mechanism 110 may be configured for establishing a high-current capable electrically conductive connection. In other words, the sideways connection between terminals 104 and connection elements 108 may be electrically and mechanically so reliable that a high current of for example at least 1 Ampere or even at least 10 Ampere may be transmitted between the electronic component 102 and the carrier 100.

Further advantageously, both the electrically conductive connection terminals 104 and the electrically conductive connection elements 108 may comprise or consist of the same metallic material (for example copper). Beneficially, this may efficiently suppress electromigration effects.

FIG. 3 illustrates a cross-sectional view of a carrier 100 and an electronic component 102 to be connected for forming a package 122 according to an exemplary embodiment prior to connection. FIG. 4 illustrates a cross-sectional view of a package 122 according to an exemplary embodiment obtained by connecting the carrier 100 and the electronic component 102 according to FIG. 3.

The embodiment of FIGS. 3 and 4 differs from the embodiment of FIGS. 1 and 2 in particular in that, according to FIGS. 3 and 4, the height misalignment balancing mechanism 110 is formed by deformable connection elements 108 in a bottom portion of the sockets 112 prior to connection. Such deformable connection elements 108 are here embodied as deformable electrically conductive medium 114, such as sinter paste comprising copper particles. This deformable electrically conductive medium 114 is inserted in the recesses delimiting the sockets 112. When the terminals 104 are inserted in the sockets 112, the deformable electrically conductive medium 114 is displaced, squeezed or pushed sideways and upwardly so that the electrically conductive medium 114 comes in direct physical contact both with the side surfaces and with the flange face of the metal pillar-type terminals 104. This ensures a reliable electric contact and enables a compensation or balancing of a potential height misalignment. Preferably, the deformable electrically conductive medium 114 and the metal pillar-type terminals 104 may be made partially or entirely of the same material, such as copper, to prevent migration phenomena. To put it shortly, the embodiment of FIGS. 3 and 4 involves sockets 112 in the carrier 100 in combination with additional deformable interconnect paste in form of the deformable electrically conductive medium 114 in said sockets 112. The latter may be for instance any kind of electrically conductive paste or glue.

FIG. 5 illustrates a cross-sectional view of a carrier 100 and an electronic component 102 to be connected for forming a package 122 according to an exemplary embodiment prior to connection. FIG. 6 illustrates a cross-sectional view of a package 122 according to an exemplary embodiment obtained by connecting the carrier 100 and the electronic component 102 according to FIG. 5.

The embodiment of FIGS. 5 and 6 differs from the embodiment of FIGS. 1 and 2 in particular in that, according to FIGS. 5 and 6, the sockets 112 of the carrier 100 are filled partially or entirely with compensation structures, such as compressible fine structures 120 (see FIGS. 14-20 for further details). Preferably, such compensation or fine structures 120 may be made of copper, and the pillars of the terminals 104 may be made of copper as well. The fine structures 120 may be solid structures, such as hairs, webs or rips, of nanometer scale with tiny gaps in between which allows compression. Upon inserting the terminals 104 in the sockets 112, said fine structures 120 may be displaced and/or compressed so as to contact the terminals 104 laterally and at a horizontal abutment surface. Advantageously, the material of the fine structures 120 may be the same as a material of the pillar-type terminals 104. Copper is an excellent choice in view of its great electrical conductivity. Material bridges and migration phenomena may be thus prevented which further improves reliability.

FIG. 7 illustrates a cross-sectional view of a carrier 100 and an electronic component 102 to be connected for forming a package 122 according to an exemplary embodiment prior to connection. FIG. 8 illustrates a cross-sectional view of a package 122 according to an exemplary embodiment obtained by connecting the carrier 100 and the electronic component 102 according to FIG. 7. FIG. 9 illustrates a plan view of carrier 100 for package 122 according to FIGS. 7 and 8. Referring to FIG. 7, an MIS carrier 100 with slotted copper sockets 112 is shown. Referring to FIG. 8, an assembly of a flip chip electronic component 102 on the MIS carrier 100 with slotted copper sockets 112 is shown. Referring to FIG. 9, a top view of the MIS carrier 100 with the slotted copper sockets 112 is illustrated.

The embodiment of FIGS. 7-9 differs from the embodiment of FIGS. 1 and 2 in particular in that, according to FIGS. 7-9, the sockets 112 protrude vertically beyond the support structure 106 rather than being integrated therein. This may simplify the insertion process in an intuitive and failure robust way. Moreover, the deformable connection elements 108 of FIGS. 7-9 comprise springy sockets 112. More specifically, the flexible electrically conductive connection elements 108 of FIGS. 7-9 are embodied as longitudinally slotted metal sleeves. As can be taken from the plan view of FIG. 9, slots may be formed in the metallic sleeves in two mutually perpendicular directions so as to form a cross-shaped structure dividing each of the metal sleeves into four elastic metal tongues 154 (any other number is possible as well). Each of said tongues 154 may be deformed to move radially outwardly upon inserting the tubular pillar-type terminals 104 into an insertion recess delimited by the four tongues 154. With such a configuration, a restoring spring force will tend to move the radially deformed tongues 154 back to their initial position and will thereby press or bias the tongues 154 laterally against the terminals 104. Advantageously, this may lead to an excellent reliability concerning the electric connection between terminals 104 and connection elements 108 even in an event of a height misalignment of the terminals 104.

As an alternative to the illustrated sockets 112 with flexible sides, it may also be possible to implement a helical electrically conductive structure having springy characteristics (not shown).

A plug-in interconnect may thus be used on substrate side. The sockets 112 of the carrier 100 constitute the female-contact for the metal pillar-type terminals 104 of the electronic component 102 providing the male-contact on chip side. Sockets 112 and terminals 104 may be made of copper. In this embodiment, any additional pillar plating, for example with tin, may be dispensable (although it is possible in yet another embodiment). The contact between the terminals 104 and the connection elements 108 may be realized by mechanical clamping, only. For this purpose, the side wall of each socket 112 may be slotted. Such copper structures can be produced by substrate manufacturing technologies. Especially MIS technology allows the formation of complex copper structures and may thus be particularly advantageous for the presently described embodiment.

Also other socket structures, like helix- or self-retain-geometries, are possible.

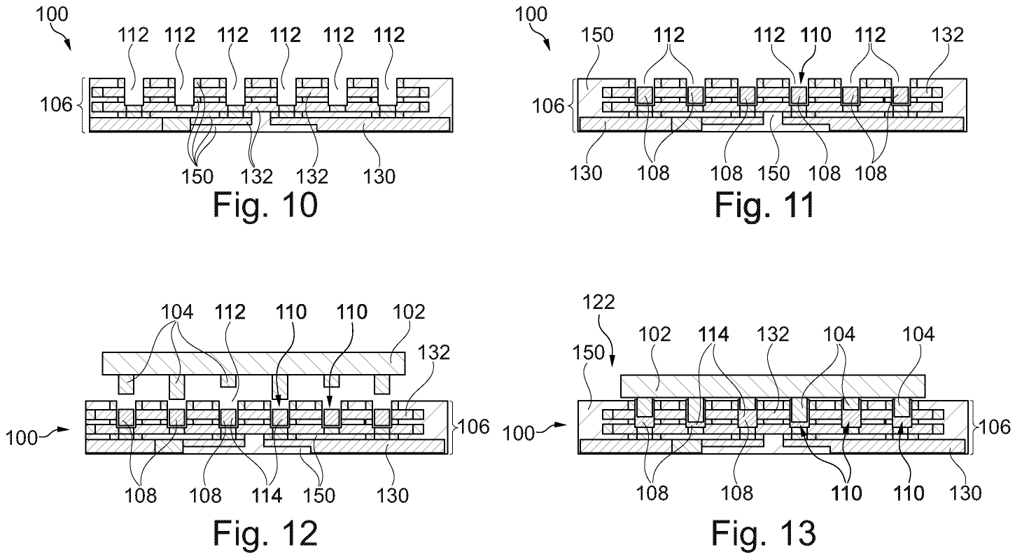

FIG. 10 illustrates a cross-sectional view of a preform of a carrier 100 for a package 122 according to an exemplary embodiment. FIG. 11 illustrates a cross-sectional view of the carrier 100 according to FIG. 10 in a completed state. FIG. 12 illustrates a cross-sectional view of the carrier 100 according to FIG. 11 and an electronic component 102 to be connected for forming the package 122. FIG. 13 illustrates a cross-sectional view of a package 122 according to an exemplary embodiment obtained by connecting the carrier 100 and the electronic component 102 according to FIG. 12.

The embodiment of FIGS. 10-13 differs from the embodiment of FIGS. 1 and 2 in particular in that, according to FIGS. 10-13, a deformable electrically conductive paste (for instance a sinter paste or a solder paste (for example comprising copper material such as copper particles) may be filled in the sockets 112 as deformable connection elements 108. Upon inserting the metal pillar forming the terminals 104 of the electronic component 102 in the sockets 112, the paste-type deformable connection elements 108 will self-sufficiently be displaced so as to reliably electrically contact both sidewalls as well as the front-sided flange face of the metal pillars. This may establish a reliable electric contact between carrier 100 and electronic component 102 and may also allow to balance any height misalignment resulting from pillar-type terminals 104 of different vertical height or length.

Referring to FIG. 10, a manufactured substrate or carrier 100 with sockets 112 for receiving cylindrical pillars is shown. Referring to FIG. 11, an interconnect material (such as a copper paste) is filled in parts of the sockets 112. Referring to FIG. 12, a flip chip configured electronic component 102 is arranged above the carrier 100 to prepare a subsequent assembly. Referring to FIG. 13, the terminals 104 of the electronic component 102 have been plugged in or inserted in the sockets 112 of the carrier 100 so that the electrically conductive paste has come into contact with the lateral surface and a horizontal surface of the terminals 104. A potential height misalignment is balanced. A reflow and/or curing process can be carried out to obtain a final interconnect. More specifically, the copper paste may be cured or hardened for fixing the terminals 104 in place for obtaining a readily manufactured package 122.

A gist of the embodiment of FIGS. 10-13 is to compensate metal pillar height deviations by using prefilled sockets 112 or holes in the support structure 106 of the carrier 100. For this purpose, electrically conductive glue, solder paste, copper paste or other materials can be used. The material may be applied by printing or dispensing into the sockets 112 before the flip chip assembly of the electronic component 102 and the carrier 100. After the assembly, a curing or reflow process can be carried out. This principle is comparable with a liquid dowel used for construction assembly. The sockets 112 can also be realized by several substrate manufacturing processes like MIS substrate technology.

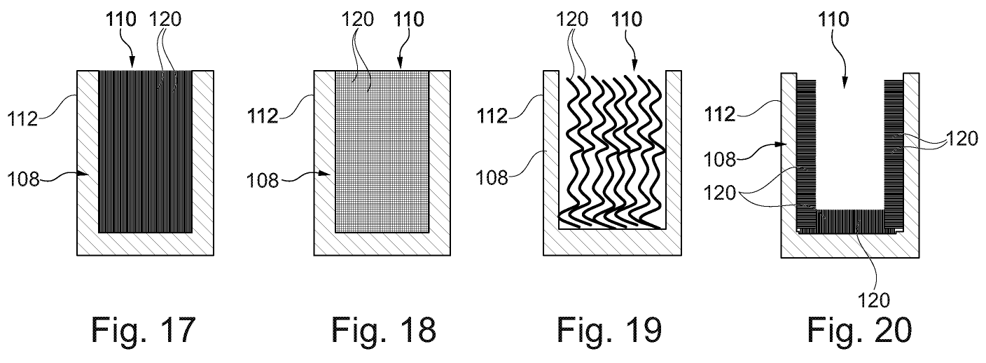

FIG. 14 illustrates a cross-sectional view of a carrier 100 and an electronic component 102 to be connected for forming a package 122 according to an exemplary embodiment prior to connection. FIG. 15 illustrates a cross-sectional view of a socket 112 of the carrier 100 according to FIG. 14. FIG. 16 illustrates a cross-sectional view of a package 122 according to an exemplary embodiment obtained by connecting the carrier 100 and the electronic component 102 according to FIG. 14 by compressive or press-together-structures. FIGS. 17-20 show examples of deformable fine structures 120.

The embodiment of FIGS. 14-20 differs from the embodiment of FIGS. 1 and 2 in particular in that, according to FIGS. 14-20, the at least partially deformable connection elements 108 in protruding sockets 112 comprise compressible or deformable fine structures 120. For example, the electrically conductive connection elements 108 comprise fine structures 120, in particular nano-structures, metallic hair structures and/or metallic ribs. Specific examples are shown in FIGS. 17-20. However, it should be said that, in other embodiments, fine structures 120 may also be formed in sockets 112 which are not protruding beyond support structure 106 but which are integrated in an interior of the support structure 106 without protruding.

Referring to FIG. 14, an MIS substrate may be provided as carrier 100 with miniature clamp structures in copper sockets 112, said clamp structures being realized by the fine structures 120. Referring to FIG. 15, a detailed view of a socket 112 with clamp-structures inside is shown. In the shown embodiment, the metallic socket 112 comprises a sleeve with closed bottom. Fine structures 120 in form of vertically protruding metal hairs are formed (for instance grown) in a recess of the socket 112. Referring to FIG. 16, a flip chip configured electronic component 102 with downward protruding metal pillar-type terminals 104 is assembled with the MIS substrate constituting the carrier 100 with the clamp structure in the metal sockets 112. This will displace the fine structures 120 laterally and/or vertically so that, inter alia, a lateral electric contact between the pillar-type terminals 104 and the fine structures 120 is established regardless of a height misalignment.

A gist of the embodiment of FIGS. 14-16 is the provision of a copper socket 112 or plug on substrate which is combined with a re-hooking structure. For this purpose, several copper structure methods can be used, see for example FIGS. 17-20. An additive manufacturing method may be carried out for forming the fine structures 120 in the sockets 112. These fine structures 120 guarantee a soft landing of all copper pillars of the terminals 104 independent of height tolerances in the socket 112. In this case, the flexible copper fine structures 120 may be displaced or compressed. By this process, a mechanical looking can be generated and the flip chip configured electronic component 102 is fixed on the substrate-type carrier 100. For an even better interlock, a post curing process can be executed. If the inner copper structure is suitable, a pure copper-copper interconnect can be realized. In this case, a temperature and pressure assembly process may be carried out.

Appropriate types of compensation or fine structures 120 are illustrated in FIGS. 17-20:

FIG. 17 illustrates a cross-sectional view of a socket 112 of a carrier 100 of a package 122 according to an exemplary embodiment. According to FIG. 17, fine structures 120 in socket 112 may be embodied as metallic nano-grass structure, for instance made of copper.

FIG. 18 illustrates a cross-sectional view of a socket 112 of a carrier 100 of a package 122 according to an exemplary embodiment. According to FIG. 18, fine structures 120 in socket 112 may be embodied as porous metal, preferably copper.

FIG. 19 illustrates a cross-sectional view of a socket 112 of a carrier 100 of a package 122 according to an exemplary embodiment. According to FIG. 19, fine structures 120 in socket 112 may be embodied as a metallic nano-grass wave, for instance made of copper.

FIG. 20 illustrates a cross-sectional view of a socket 112 of a carrier 100 of a package 122 according to an exemplary embodiment. According to FIG. 20, fine structures 120 in socket 112 may be embodied as metallic side wall structure, in particular made of copper. The fine structures 120 embodied as metallic side wall structure may be formed on sidewalls and a bottom wall of the sleeve-shaped socket 120 with closed bottom, leaving a recess in a central portion of the sleeve 112. This configuration may provide a self-centering function when inserting pillar-type terminals 104 in the socket 112.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A carrier for carrying and electrically connecting an electronic component comprising a plurality of downwardly protruding electrically conductive connection terminals for connection with the carrier, the carrier comprising:
a support structure configured to support the electronic component;
a plurality of electrically conductive connection elements each configured to establish an electrically conductive connection with an assigned one of the electrically conductive connection terminals of the electronic component when the electronic component is supported by the support structure; and
a height misalignment balancing mechanism integrated in the carrier and configured to balance a height misalignment between respective pairs of one of the electrically conductive connection elements and an assigned one of the electrically conductive connection terminals by electrically contacting the connection terminals laterally with the connection elements when the connection terminals are connected with the connection elements.

2. The carrier of claim 1, wherein the support structure comprises a plurality of sockets in which the height misalignment balancing mechanism is integrated, wherein each socket comprises a respective one of the electrically conductive connection elements and is configured to receive a plugged-in respective electrically conductive connection terminal of the electronic component.

3. The carrier of claim 2, wherein the sockets are formed in recesses in the support structure and/or protrude vertically beyond the support structure.

4. The carrier of claim 1, wherein the height misalignment balancing mechanism comprises at least partially deformable connection elements.

5. The carrier of claim 4, wherein at least one of:
the at least partially deformable connection elements comprise a deformable electrically conductive medium;
the at least partially deformable connection elements form part of deformable sockets; and
the at least partially deformable connection elements comprise deformable fine structures.

6. The carrier of claim 1, wherein the height misalignment balancing mechanism is formed by a plurality of flexible electrically conductive connection elements.

7. The carrier of claim 6, wherein the support structure comprises a plurality of sockets in which the height misalignment balancing mechanism is integrated, wherein each socket comprises a respective one of the electrically conductive connection elements and is configured to receive a plugged-in respective electrically conductive connection terminal of the electronic component, and wherein the flexible electrically conductive connection elements are arranged at a lateral wall of the sockets.

8. The carrier of claim 6, wherein the flexible electrically conductive connection elements are helical structures or leaf springs.

9. The carrier of claim 6, wherein the flexible electrically conductive connection elements are slotted sleeves.

10. The carrier of claim 1, wherein the electrically conductive connection elements comprise nano-structures, metallic hair structures, porous metal structures, metallic wave structures, metallic side wall structures, and/or metallic ribs.

11. The carrier of claim 1, wherein the height misalignment balancing mechanism is configured to connect the electrically conductive connection elements with the electrically conductive connection terminals by mechanically clamping only.

12. The carrier of claim 1, wherein at least one of:
the support structure is configured as one of a molded interconnect substrate, a laminate substrate, a ceramic substrate and a leadframe structure;
the height misalignment balancing mechanism is configured to balance misalignment by arranging the connection elements at sockets for connection to a sidewall of the connection terminals when plugged in the sockets; and
the support structure comprises a plurality of exposed electrically conductive pads at a bottom of the support structure and comprises a plurality of internal electrically conductive traces, the traces electrically connecting the connection elements to the pads.

13. A package, comprising:
the carrier of claim 1; and
the electronic component supported by the support structure of the carrier,
wherein the downwardly protruding electrically conductive connection terminals of the electronic component are connected with the carrier,
wherein an electrically conductive connection is established between respective pairs of one of the electrically conductive connection elements and an assigned one of the electrically conductive connection terminals between which the height misalignment balancing mechanism balances a height misalignment by electrically contacting the connection terminals laterally with the connection elements.

14. The package of claim 13, wherein the electronic component is connected with the carrier in a flip-chip configuration.

15. The package of claim 13, wherein the electrically conductive connection terminals and the electrically conductive connection elements are configured to establish a high-current capable electrically conductive connection.

16. The package of claim 13, wherein the electrically conductive connection terminals and the electrically conductive connection elements comprise a same material.

17. The package of claim 13, wherein the electronic component is a semiconductor chip.

18. The package of claim 13, wherein at least two different ones of the downwardly protruding electrically conductive connection terminals have different heights.

19. The package of claim 13, wherein the downwardly protruding electrically conductive connection terminals comprise metal pillars and/or metal pads.

20. A method of manufacturing a carrier for carrying and electrically connecting an electronic component comprising a plurality of downwardly protruding electrically conductive connection terminals for connection with the carrier, the method comprising:
providing a support structure for supporting the electronic component to be carried;
forming a plurality of electrically conductive connection elements at the support structure and each configured to establish an electrically conductive connection with an assigned one of the electrically conductive connection terminals of the electronic component when the electronic component is supported by the support structure; and
integrating a height misalignment balancing mechanism in the support structure and
configuring the height misalignment balancing mechanism to balance a height misalignment between respective pairs of one of the electrically conductive connection elements and an assigned one of the electrically conductive connection terminals by electrically contacting the connection terminals laterally with the connection elements when the connection terminals are connected with the connection elements.
